(19) United States
(12) Patent Application Publication
(10) Pub. No.: US 2002/0100412 A1
(43) Pub. Date: Aug. 1, 2002

(54) Low dislocation buffer and process for production thereof as well as device provided with low dislocation buffer

(76) Inventors: Hideki Hirayama, Wako-shi (JP); Yoshinobu Aoyagi, Wako-shi (JP); Akira Hirata, Tokyo (JP)

Correspondence Address: BIRCH STEWART KOLASCH & BIRCH, PO BOX 747, FALLS CHURCH, VA, 22040-0747, US

(21) Appl. No.: 09/943,222

(22) Filed: Aug. 31, 2001

(30) Foreign Application Priority Data
Dec. 4, 2000 (JP) 2000-368566

(51) Int. Cl. C30B 25/00; C30B 23/00; C30B 28/12; C30B 28/14

(52) U.S. Cl. 117/89

(57) ABSTRACT

To provide a low dislocation buffer, which can be formed by a simple process for a short period of time, and there is no fear of producing cracks, a first layer made of a nitride semiconductor containing an impurity at a concentration exceeding its doping level is laminated a predetermined number of times alternately with a second layer made of a nitride semiconductor containing no impurity on a substrate to form a superlattice structure in a low dislocation buffer formed between the substrate and a nitride semiconductor as a device material to be formed for constituting a device structure on the substrate.

### BACKGROUND OF THE INVENTION

1. Field of The Invention

The present invention relates to a low dislocation buffer and a process for the production thereof as well as a device provided with a low dislocation buffer, and more particularly to a low dislocation buffer used suitably for a buffer layer formed between a substrate made of a variety of materials and an epitaxial semiconductor layer being a thin or thick film of a nitride semiconductor such as GaN (gallium nitride) in the case where such epitaxial semiconductor layer is applied on the substrate to form a device material for constituting a predetermined device structure, and a process for the production of such low dislocation buffer as well as to a variety of devices such as light-emitting device, light-receiving device, and electron device each of which is provided with such low dislocation buffer.

2. Description of the Related Art

In recent years, attention is being given to GaN that is one of three-five nitride semiconductors as a device material for constituting a device structure of light-emitting device in a short wavelength region extending from blue wavelength region to ultra violet wave length region. Recently, blue light-emitting diode (LED) is realized as a light-emitting device the device structure of which is formed by using a GaN-based thin film as a device material. Besides, a study for light-emitting device such as blue laser, light-receiving device or electron device a device structure of which is formed by using a GaN-based thin film as a device material is also carried forward.

It is to be noted that not only GaN, but also three-five nitride semiconductors such as AlGaN and InGaN are known as a GaN-based thin film.

It has been pointed out that threading dislocation density (number of threading dislocation per unit area) existing in an nitride semiconductor such as a GaN-based thin film must be reduced in order either to increase efficiency in light emission of blue LED the device structure of which is formed by using a nitride semiconductor such as a GaN-based thin film as a device material, or to realize a varieties of light-emitting device such as blue laser, light-receiving element, and electron device a device structure of which is formed by using a GaN-based thin film as a device material.

More specifically, such threading dislocation influences directly decrease in light-emitting efficiency and light-emitting life of a light-emitting device, increase in dark current, increase in leakage current of junction transistor and field effect transistor, so that a technique for reducing threading dislocation is considered to be very important.

Incidentally, there has been no substrate that can lattice-match with a nitride semiconductor until now as a substrate used in the case where a nitride semiconductor is epitaxially grown thereon. For this reason, a current condition is such that a sapphire (Al₂O₃) or silicon carbide (SiC) substrate, which has been heretofore widely employed as a substrate applied in case of epitaxial growth of other three-five semiconductors (such as gallium arsenide (GaAs), and indium phosphide (InP)) than nitride semiconductors is used widely.

In this respect, it has been arranged in such that a nitride semiconductor such as AlGaN is formed on such a sapphire or silicon carbide substrate as a buffer, and a nitride semiconductor used as a device material for constituting a device structure is epitaxially grown on such buffer layer made of the nitride semiconductor.

However, when a threading dislocation density in a nitride semiconductor buffer formed as a buffer layer on the above-described sapphire or silicon carbide substrate is compared with that of other three-five semiconductors (such as GaAs, and InP), which have been formed on the sapphire or silicon carbide substrate and has been in practical application, the former threading dislocation density is extremely high due to a difference in lattice constant between the sapphire or silicon carbide substrate and the nitride semiconductor.

Since a threading dislocation density in a nitride semiconductor formed as a device material for constituting a device structure on a buffer layer depends upon a threading dislocation density in the buffer layer, reduction of a threading dislocation density in the buffer layer has been a very important problem.

More specifically, it has been arranged heretofore as shown in FIG. 1, which is a sectional explanatory view illustrating schematically a conventional buffer structure, in such that an Al_{0.15}Ga_{0.75}N buffer 104 having 800 nm film thickness was formed on a substrate 100 made of 6H-SiC (0001) through a thin film 102 made of AlN (aluminum nitride).

On the buffer layer 104, a thin film 106 for estimating threading dislocation density that is used for the estimation of a threading dislocation density is formed. The thin film 106 for estimating threading dislocation density is a thin film made from In_{0.2}Ga_{0.8}N formed at a low temperature into a film having 100 nm thickness, and it is used only for the estimation of a threading dislocation density according to SEM or TEM. Threading dislocation density is estimated on the basis of a growth pit density of the thin film 106 for estimating threading dislocation density.

Accordingly, it is not required for the case where a nitride semiconductor is epitaxially grown as a device material for constituting a device structure on the buffer layer 104.

FIG. 2 is an SEM image of a surface in the thin film 106 for estimating threading dislocation density where in deep colored circular sites in the SEM image are threading dislocations, and there is clearly shown an appearance of threading dislocations at a high density.

As a specific example, when a buffer 104 made of Al_{0.15}Ga_{0.75}N is formed on a substrate 100 made of 6H-SiC (0001) with 800 nm film thickness, threading dislocations appear at a high density of 10⁹ cm⁻² to 10¹¹

In view of the above description, it has been proposed to form a buffer of a nitride semiconductor having a low threading dislocation density on a sapphire or silicon carbide substrate in accordance with, for example, ELO (Epitaxially Lateral Overgrowth) technique or Pendeo-Epitaxy technique as a manner for reducing a threading dislocation density of a nitride semiconductor formed on a sapphire or silicon carbide substrate as a buffer.

However, in order to form a buffer of a nitride semiconductor in accordance with the above-described ELO or Pendeo-Epitaxy technique, there have been such problems that operations therefor become complicated, and that a time required for operations increase also because of accompanying with complicated processes.

Furthermore, it is required to form a buffer having a thick film thickness of at least around several microns for attaining a flat surface in order to form a buffer of a nitride semiconductor in accordance with the above-described ELO or Pendeo-Epitaxy technique. Hence, there have been problems of requiring a long period of time for forming such buffer of a thick thickness, and of generating cracks as a result of formation of a thick film.

Object and Summary of the Invention

The present invention has been made in view of the above described various problems involved in the prior art, and an object of the invention is to provide a low dislocation buffer and a process for the production thereof as well as a device provided with such low dislocation buffer. The above-described low dislocation buffer is the one having a low dislocation density and formed between a substrate made of a variety of materials and an epitaxial semiconductor layer of a thin or thick film of a nitride semiconductor such as GaN as a device material for constituting a predetermined device structure. In case of preparing the above-described buffer, neither complicated process is required, nor thick film is required for making the surface thereof flat, whereby the film can be formed by a simple process for a short period of time, and there is no fear of generating cracks.

In order to achieve the above-described objects, a low dislocation buffer formed between a substrate and a nitride semiconductor as a device material to be formed for constituting a device structure on the substrate according to the present invention comprises a first layer made of a nitride semiconductor containing an impurity at a concentration exceeding its doping level being laminated a predetermined number of times alternately with a second layer made of a nitride semiconductor containing no impurity on the substrate to form a superlattice structure.

In such a low dislocation buffer constituted based on a superlattice structure prepared by laminating a first layer made of a nitride semiconductor containing an impurity at a concentration exceeding its doping level a predetermined number of times with a second layer made of a nitride semiconductor containing no impurity as in the above-described invention, a threading dislocation density is reduced to, for example, “5×10⁷ Cm⁻²”.

In the above-described invention, a concentration of an impurity contained in a nitride semiconductor for forming the above-described first layer may be 10¹⁸ cm⁻³ to 10%.

Furthermore, in the above-described invention, the above-described impurity may be Si (silicon), C (carbon), Mg (magnesium), or O (oxygen).

Moreover, in the above-described invention, a nitride semiconductor for forming the above-described first layer or the second layer is a three-five nitride semiconductor.

Still further, in the above-described invention, the above-described substrate may be made from Si (silicon), SiC (silicon carbide), Al₂O₃ (sapphire), or GaAs (gallium arsenide).

Furthermore, a process for the production of a low dislocation buffer formed between a substrate and a nitride semiconductor as a device material to be formed for constituting a device structure on the substrate according to the present invention, comprises a first step for forming either of a first layer made of a nitride semiconductor containing an impurity at a concentration exceeding its doping level or a second layer made of a nitride semiconductor containing no impurity; a second step for forming either layer of the first layer and the second layer, which has not yet been formed by the first step on the layer, which has been formed by the first step; and the first step and the second step being alternately repeated a predetermined number of times to laminate the first layer alternately with the second layer on the substrate at the predetermined number of times to form a superlattice structure.

According to the above-described present invention, a low dislocation buffer a threading dislocation density of which has been reduced to, for example, “5×10⁷cm⁻²” is formed based on a superlattice structure prepared by laminating a first layer made of a nitride semiconductor containing an impurity at a concentration exceeding its doping level a predetermined number of times with a second layer made of a nitride semiconductor containing no impurity as a result of repeating to laminate alternately the above-described first step the predetermined number of times with the above-described second step. As a result, a low dislocation buffer having a thin film thickness can be formed by a simple process for a short period of time, and there is no fear of producing cracks.

In the above-described present invention, a concentration of an impurity contained in a nitride semiconductor for forming the above-described first layer may be substantially 1% or more.

Furthermore, in the above-described present invention, the above-described impurity may be Si (silicon), C (carbon), Mg (magnesium), or O (oxygen).

Moreover, in the above-described present invention, a nitride semiconductor for forming the above-described first layer or the second layer may be a three-five nitride semiconductor.

Still further, in the above-described present invention, the above-described substrate may be made from Si (silicon), SiC (silicon carbide), Al₂O₃ (sapphire), or GaAs (gallium arsenide).

Furthermore, the present invention relates to a device provided with a low dislocation buffer comprises the above-described low dislocation buffer being prepared by forming a predetermined device structure on the low dislocation buffer of the above-described present invention with the use of a nitride semiconductor as a device material.

Moreover, in the above-described present invention, a nitride semiconductor that comes to be a device material for constituting the above-described device structure may be a three-five nitride semiconductor.

### BRIEF DESCRIPTION OF THE DRAWING

The present invention will become more fully understood from the detailed description given hereinafter and the accompanying drawings which are given by way of illustration only, and thus are not limitative of the present invention, and wherein:

FIG. 1 is a sectional explanatory view showing schematically a structure of a conventional buffer;

FIG. 2 is a SEM image showing a surface of a thin film for estimating threading dislocation density in the structure shown in FIG. 1;

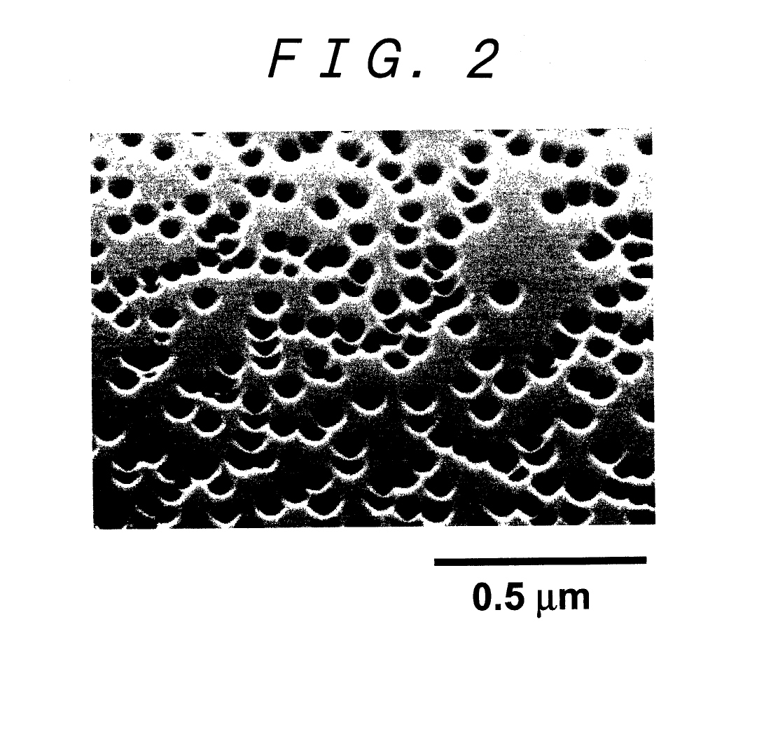

FIG. 3 is a sectional explanatory view showing schematically a structure of an example of a preferred embodiment of a low dislocation buffer according to the present invention;

FIG. 4 is an SEM image showing a surface of a thin film for estimating threading dislocation density in the structure shown in FIG. 3;

FIG. 5 is a conceptual block diagram for explaining a structure of a system for producing a low dislocation buffer according to the present invention;

FIG. 6 is a timing chart for indicating timings for feeding a carrier gas and a material gas into a crystal growth reactor;

FIG. 7 is a graphical representation indicating a relationship between TESi flow rate and threading dislocation density in a low dislocation buffer according to the present invention;

FIG. 8 is a graphical representation indicating a relationship between periodicity in a low dislocation buffer layer according to the present invention and threading dislocation density in the low dislocation buffer layer thereof;

FIG. 9 is a TEM image showing a section of the structural body shown in FIG. 3;

FIG. 10 is a graphical representation indicating a relationship between periodicity in a low dislocation buffer layer according to the present invention and threading dislocation density in the low dislocation buffer layer thereof;

FIG. 11 is a perspective view showing a nitride semiconductor HFET (Heterostructure Field Effect Transistor) provided with a low dislocation buffer layer according to the present invention; and

FIG. 12 is a perspective view showing a nitride semiconductor laser diode provided with a low dislocation buffer layer according to the present invention.

### DETAILED DESCRIPTION OF THE PREFERRED EMBODIMENTS

In the following, one example of a preferred embodiment of a low dislocation buffer and a process for the production thereof as well as a device provided with the low dislocation buffer according to the present invention will be described in detail by referring to the accompanying drawings.

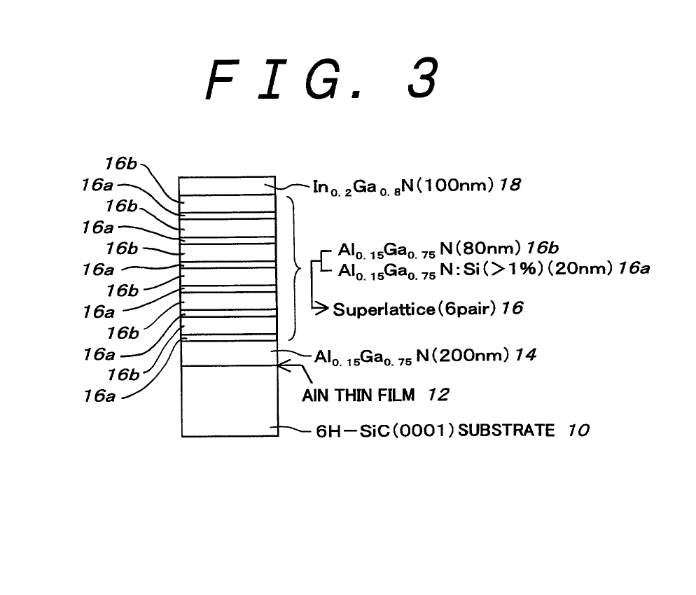

FIG. 3 is a sectional explanatory view showing schematically a structure of an example of a preferred embodiment of a low dislocation buffer according to the present invention wherein an AlN thin film is formed on a substrate 10 made of 6H-SiC (0001) as a first initial layer 12, and an Al_{0.15}Ga_{0.75}N is formed thereon with 200 nm film thickness as a second initial layer 14.

Furthermore, on the second initial layer 14 of Al_{0.15}Ga_{0.75}N is formed a low dislocation buffer of a superlattice structure, as a buffer layer 16, prepared by laminating a layer 16a of a nitride semiconductor containing impurities at a high concentration (hereinafter referred to as “high-concentration impurity-containing nitride semiconductor”) made of the high-concentration impurity-containing nitride semiconductor a predetermined number of times alternately with a layer 16b of a nitride semiconductor containing no impurity (hereinafter referred to as “non impurity-containing nitride semiconductor” made of the non impurity-containing nitride semiconductor.

In_{0.2}Ga_{o.8}N, which has been formed with a film thickness of 100 nm, is formed on the low dislocation buffer layer 16 involving a superlattice structure as a thin film 18 for estimating threading dislocation density. The thin film 18 for estimating threading dislocation density made of In_{0.2}Ga_{0.8}N was formed at a low temperature for estimation of threading dislocation density by means of SEM or TEM, and this is not necessary for the case where a nitride semiconductor is epitaxially grown on the low dislocation buffer layer 16.

In the following, a low dislocation buffer for preparing the low dislocation buffer layer 16 involving a supperlattice structure will be described in detail.

First, a high-concentration impurity-containing nitride semiconductor for the high-concentration impurity-containing nitride semiconductor layer 16a is, for example, AlGaN containing Si (silicon) at a high concentration as an impurity (hereinafter referred optionally to as “Si-containing AlGaN”). More specifically, Al_{0.5}Ga_{0.75}N containing Si at 1% concentration, i.e., “1.2×10²⁰ [atoms/cm³] (SIMS)” is used as a high-concentration impurity-containing nitride semiconductor in the present embodiment, and the Al_{0.15}Ga_{0.75}N containing Si is formed with 20 nm film thickness to obtain the high-concentration impurity-containing nitride semiconductor layer 16a.

Then, a non impurity-containing nitride semiconductor for preparing a non impurity-containing nitride semiconductor layer 16b is, for example, AlGaN. More specifically, Al_{0.15}Ga_{0.75}N is used as a non impurity-containing nitride semiconductor in the present embodiment, and the Al_{0.15}Ga_{0.75}N is formed with 80 nm film thickness to obtain the non impurity-containing nitride semiconductor layer 16b.

On the second initial layer 14, the high-concentration impurity-containing nitride semiconductor layer 16a is laminated a predetermined number of times alternately with the non impurity-containing nitride semiconductor layer 16b to form a superlattice structure of the high-concentration impurity-containing nitride semiconductor layer 16a and the non impurity-containing nitride semiconductor layer 16b, and this corresponds to a low dislocation buffer for forming the low dislocation buffer layer 16.

More specifically, a continuous high-concentration impurity-containing nitride semiconductor layer 16a and non impurity-containing nitride semiconductor layer 16b are made to be a pair as a period, and an amount of six pairs of the high-concentration impurity-containing nitride semiconductor layer 16a and the non impurity-containing nitride semiconductor layer 16b, i.e., six periods of both the layers are laminated in the present embodiment. Accordingly, a layer thickness of the low dislocation buffer layer 16 is 600 nm in the present embodiment.

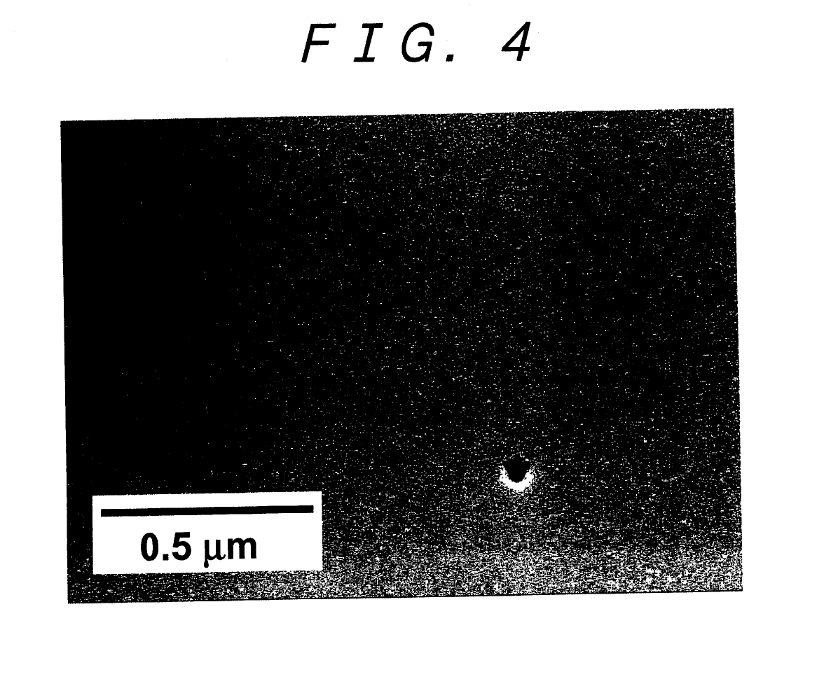

FIG. 4 shows an SEM image on a surface of the thin film 18 for estimating threading dislocation density of a structural member made of InGaN shown in FIG. 3 wherein deep-colored circular sites correspond to threading dislocations in the SEM image, and it was found that the threading dislocations were only produced at a very low density.

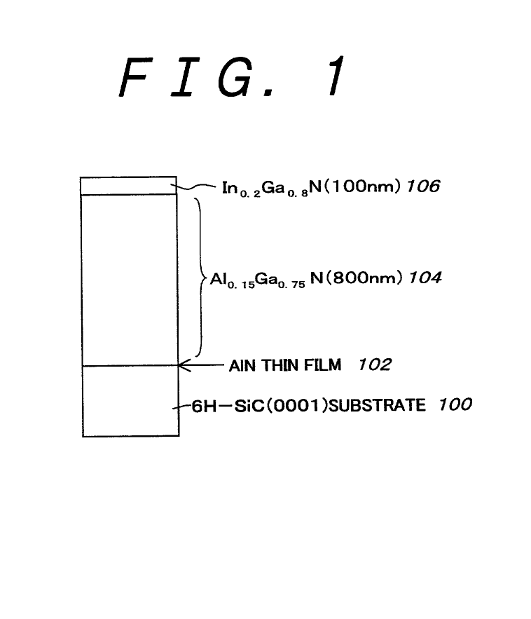

Specifically, a threading dislocation density of a structural member provided with the above-described conventional buffer 104 prepared in accordance with a condition shown in FIG. 1 as a buffer layer was “2×10¹⁰ cm⁻²”, while a threading dislocation density of a structure member provided with the low dislocation buffer layer 16 of the above-described embodiment prepared in accordance with a condition as shown in FIG. 3 decreased to “5×10⁷ Cm⁻²”.

It is to be noted that threading dislocation density was estimated from a growth pit density of the thin film 18 for estimating threading dislocation density as described above.

Moreover, as mentioned in detail hereunder, compositions of the substrate 10, the first initial layer 12, the second initial layer 14, the low dislocation buffer layer 16 and the thin film 18 for estimating threading dislocation density are not particularly limited to that of the above-described embodiment.

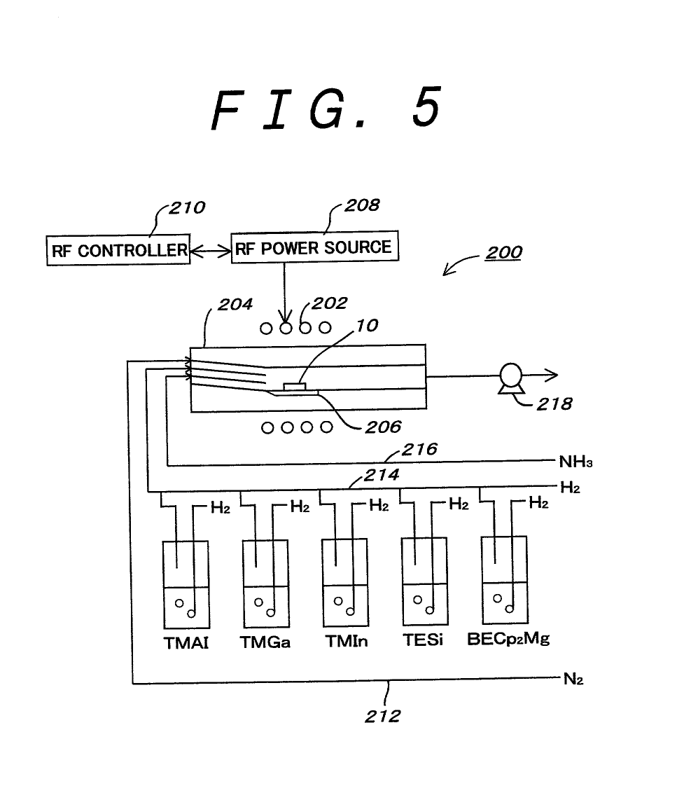

Next, details of a process for the production of the low dislocation buffer layer 16 in the above-described embodiment shown in FIGS. 3 and 4 will be described by referring to FIG. 5 being a conceptual explanatory view showing a structure of a system for producing the low dislocation buffer layer 16 shown in FIGS. 3 and 4.

The production system shown in FIG. 5 is a crystal growth apparatus for carrying out MOCVD (Metalorganic Chemical Vapor Deposition) method. According to the crystal growth apparatus, a variety of thin and thick films can be produced on a variety of substrates 10 (6H-SiC (0001) is used in the present embodiment as the substrate 10) such as silicon carbide (SiC), sapphire (Al₂O₃), silicon (Si) and gallium arsenide (GaAs).

In a crystal growth apparatus 200, the substrate 10 is placed on the upper surface inside a crystal growth reactor 204 around the circumference of which is covered by an RF heating coil 202, wherein the first initial layer 12, the second initial layer 14, the low dislocation buffer layer 16, and the thin film 18 for estimating threading dislocation density are subjected to crystal growth on the substrate 10, and further a susceptor 206 for heating the substrate 10 is mounted.

Furthermore, an RF power source 208 is connected to the RF heating coil 202, and further an RF controller 210 composed of a microcomputer is connected to the RF power source 208.

An output of the RF power source 208 is controlled by means of the RF controller 210. More specifically, power feed from the RF power source 208 with respect to the RF heating coil 202 is controlled by the RF controller 210, and a susceptor 206 is heated in response to the power feed from the RF electrode 208 by means of the RF heating coil 202.

More specifically, the susceptor 206 is heated by means of overcurrent induction heating due to the power feed from the RF power source 208 to the RF heating coil 202 in the crystal growth apparatus 200.

In this case, the susceptor 206 is formed from, for example, carbon and the like.

Furthermore, a first introducing pipeline 212, a second introducing pipeline 214, and a third introducing pipeline 216 are disposed, respectively, as pipelines for introducing a variety of gases such as material gases being materials for the first initial layer 12, the second initial layer 14, the low dislocation buffer layer 16, and the thin film 18 for estimating threading dislocation density, all of them being to be formed on the substrate 10 as well as carrier gases into the crystal growth reactor 204.

More specifically, nitrogen (N₂) gas is supplied into the crystal growth reactor 204 through the first introducing pipeline 212 as a carrier gas.

Furthermore, trimethylaluminum (TMAl), trimethylgallium (TMGa), and trimethylindium (TMIn) that come to be the group III nitride sources in three-five nitride semiconductors are supplied together with hydrogen (H₂) gas, as a carrier gas, into the crystal growth reactor 204 through the second introducing pipeline 214, and at the same time, TESi that comes to be a supply source of Si being an impurity is supplied into the crystal growth reactor 204.

Through the second introducing pipeline 214, BECp₂Mg is also supplied with hydrogen (H₂) gas, as a carrier gas, into the crystal growth reactor 204.

Through the third introducing pipeline 216, ammonia (NH₃) that becomes the group V source in three-five nitride semiconductors is supplied into the crystal growth reactor 204.

Reference character 218 designates a rotary pump for reducing a pressure to 0.1 atmosphere (76 Torr) in the crystal growth reactor 204.

In the above-described structure, to prepare a crystal thin film of the first initial layer 12, the second initial layer 14, the low dislocation buffer layer 16, and the thin film 18 for estimating threading dislocation density on the substrate 10 placed in the susceptor 206, the above-described various material gases are supplied into the crystal growth reactor 204 an inner pressure of which has been reduced to 76 Torr by means of the rotary pump 218 together with carrier gases through the first introducing pipeline 212, the second introducing pipeline 214, and the third introducing pipeline 216.

In this case, the susceptor 206 has been heated by means of the RF heating coil 202 in response to power supply from the RF power source 208 controlled by the RF controller 210 on the basis of a monitor of a thermocouple (not shown) embedded in the susceptor 206, and due to heat conduction from the heated susceptor 206, the substrate 10 is also heated at a growth temperature, which is suitable for preparing a crystal thin film of the first initial layer 12, the second initial layer 14, the low dislocation buffer layer 16, and the thin film 18 for estimating threading dislocation density in accordance with crystal growth.

Thus, the material gases which have been introduced into the crystal growth reactor 204 are decomposed by heat to react with each other to form a crystal thin film of the first initial layer 12, the second initial layer 14, the low dislocation buffer layer 16, and the thin film 18 for estimating threading dislocation density on the substrate 10 in accordance with crystal growth.

In this case, each flow rate of carrier gases and material gases required for preparing a crystal thin film of the first initial layer 12, the second initial layer 14, the low dislocation buffer layer 16, and the thin film 18 for estimating threading dislocation density is as follows.

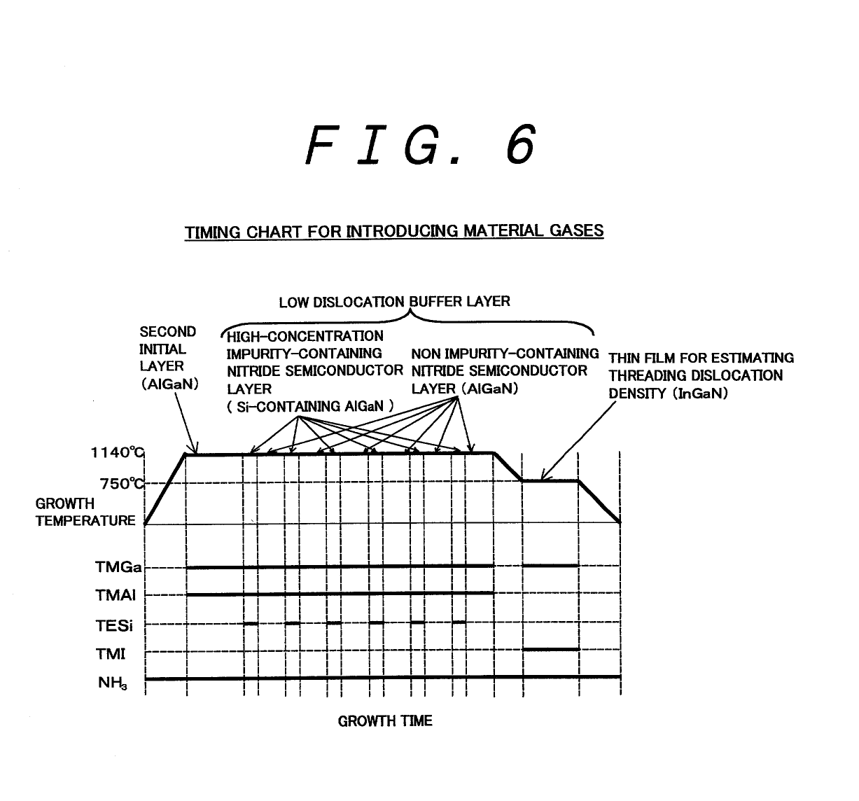

Furthermore, timings for supplying the carrier gases and the material gases into the crystal growth reactor 204 as well as growth temperatures of crystal growth are as shown in the timing chart of FIG. 6.

(1) First Initial Layer 12 . . . Preparation of AlN Thin Film

| | | |
|---|---|---|
| Material gases: | TMA1 | 7 μmol/min |
| | NH₃ | 2 L/min |
| Carrier gas: | H₂ | 2 L/min |

(2) Second Initial Layer 14 . . . Preparation of AlGaN

| | | |
|---|---|---|
| Material gases: | TMGa | 38 μmol/min |
| | TMA1 | 7 μmol/min |
| | NH₃ | 2 L/min |
| Carrier gas: | H₂ | 2 L/min |

(3) Low Dislocation Buffer Layer 16 . . . Preparation of High-Concentration Impurity-Containing Nitride Semiconductor Layer 16a (Si-Containing AlGaN) and Non Impurity-Containing Nitride Semiconductor Layer 16b (AlGaN)

| | | |
|---|---|---|
| Material gases: | TMGa | 38 μmol/min |
| | TMA1 | 7 μmol/min |
| | NH₃ | 2 L/min |
| | TESi | 4 nmol/min |
| Carrier gas: | H₂ | 2 L/min |

Si concentration: 1.2×10²⁰ [atmos/cm³] (SIMS)

(4) Thin Film 18 for Estimating Threading Dislocation Density . . . Preparation of InGaN

| | | |
|---|---|---|
| Material gases: | TMGa | 1.5 μmol/min |
| | TMIn adduct | 30 μmol/min |
| | NH₃ | 2 L/min |
| Carrier gas: | N₂ | 1 L/min |

As shown in FIG. 6, since a crystal growth temperature of crystal growth in case of preparing a crystal thin film of second initial layer 14 and low dislocation buffer layer 16 is 1140° C., substrate 10 is heated in such that a temperature thereof becomes 1140° C., while since a crystal growth temperature of crystal growth is 750° C. in case of preparing a crystal thin film of thin film 18 for estimating threading dislocation density, the substrate 10 is heated in such that a temperature thereof becomes 750° C.

A growth rate of a crystal thin film of first initial layer 12, second initial layer 14, and low dislocation buffer layer 16 is 2.4 μm/hour, and a growth rate of a crystal thin film of thin film 18 for estimating threading dislocation density has been set to 0.1 μm/hour.

According to a low dislocation buffer layer 16 thus prepared, a very low threading dislocation density of 10⁷-order can be realized as described above.

After forming the low dislocation buffer layer 16, when a nitride semiconductor such as GaN is formed on the low dislocation buffer layer 16 in the crystal growth reactor 204 without forming the thin film 18 for estimating threading dislocation density on the low dislocation buffer layer 16, a nitride semiconductor can be formed at a low dislocation density.

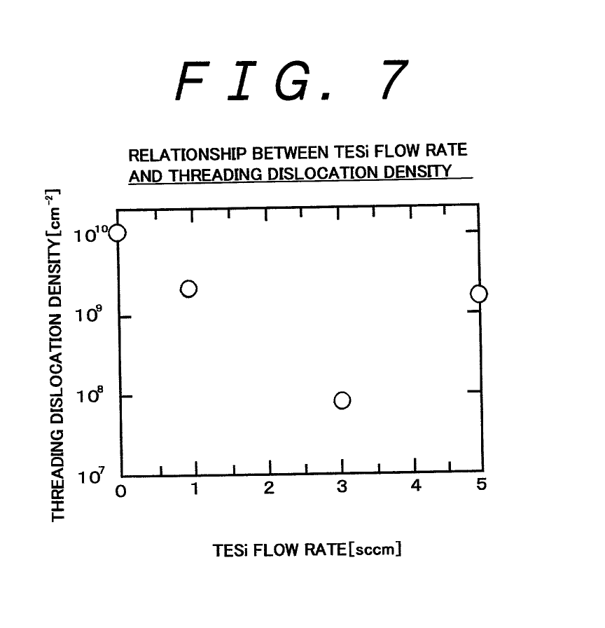

The present inventor was measured changes in threading dislocation density of a low dislocation buffer layer 16 in the case where only a flow rate of TESi being a source for supplying impurity Si is changed in the same conditions as that described above, and the results thereof shown in the graph of FIG. 7.

As shown in the graphical representation indicating a relationship between flow rate of TESi and threading dislocation density in the low dislocation buffer layer 16 of FIG. 7, a threading dislocation density in the low dislocation buffer layer 16 decreases with increase in a TESi flow rate until the flow rate reaches a certain value. Accordingly, it is recognized that threading dislocation density in the low dislocation buffer layer 16 depends upon TESi flow rate.

On the other hand, when the TESi flow rate exceeds a certain value, threading dislocation density in the low dislocation buffer layer 16 increases on the contrary. This phenomenon is considered to be in such that when a concentration of Si in a high-concentration impurity-containing nitride semiconductor layer 16a becomes too high, crystallizability comes to be poor, so that threading dislocation does not decrease.

Accordingly, when a concentration of impurity in high-concentration impurity-containing nitride semiconductor layer 16a is properly selected, it becomes possible to efficiently decrease threading dislocation density. For instance, when a high-concentration impurity-containing nitride semiconductor layer 16a is prepared from Al_{0.15}Ga_{0.75}N containing Si as an impurity, an Si concentration is preferably within a range of from 10¹⁸ cm−3 to 10%, and most effectively within a range of from 10¹⁹ cm−3 to 1% in the former range.

As mentioned hereunder, a composition of a nitride semiconductor constituting a high-concentration impurity-containing nitride semiconductor layer 16a as well as a type of impurities are not specifically limited, but in such a case, a concentration of impurity is preferably within a range of from 10¹⁸ cm⁻³ to 10%, and most effectively within a range of from 10¹⁹ cm⁻³ to 1% in the former range.

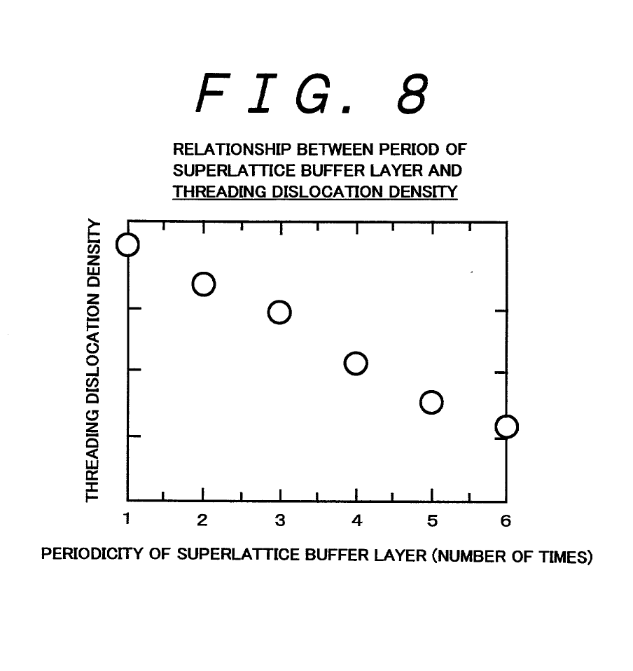

Next, the present inventor was measured changes in threading dislocation density of a low dislocation buffer layer 16 in the case where only a periodicity of a low dislocation buffer layer 16 is changed in the same conditions as that described above, and the results thereof shown in the graph of FIG. 8.

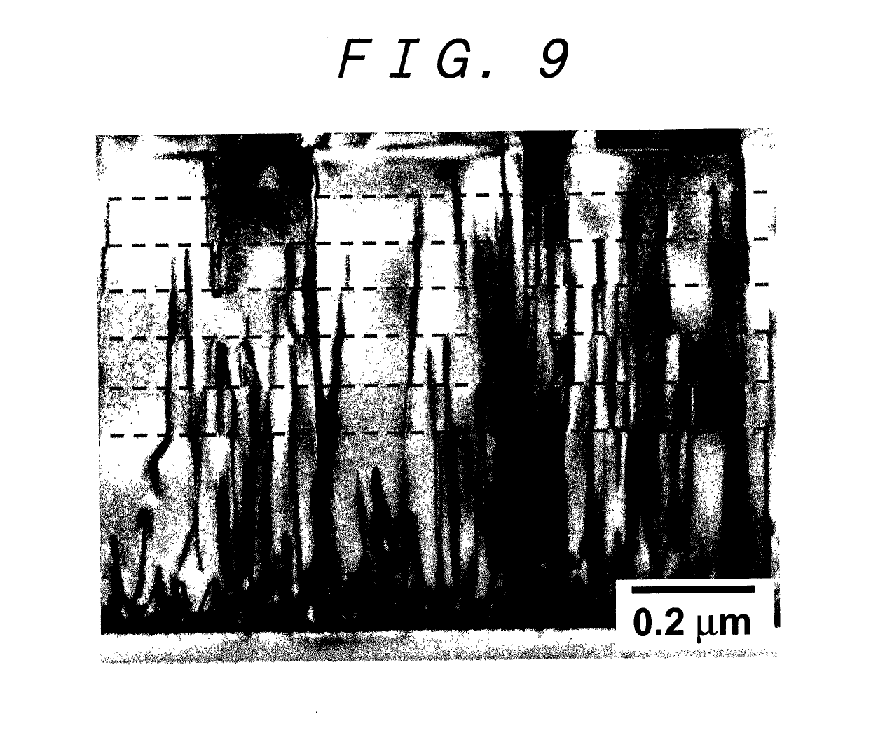

Moreover, FIG. 9 shows a TEM image of a section of a low dislocation buffer layer 16 wherein deep-colored sites indicate threading dislocations, while broken lines extending in the horizontal direction indicate interfaces each defined between a high-concentration impurity-containing nitride semiconductor layer 16a and a non impurity-containing nitride semiconductor layer 16b.

As appeared in the graph of FIG. 8 indicating a relationship between periodicity of a low dislocation buffer layer 16 and threading dislocation density in the low dislocation buffer layer 16, threading dislocations disappear gradually in each interface defined between a high-concentration impurity-containing nitride semiconductor layer 16a and a non impurity-containing nitride semiconductor layer 16b with increase in periodicity of the low dislocation buffer layer 16.

As a result, it is recognized that threading dislocation density in the low dislocation buffer layer 16 depends on periodicity of the low dislocation buffer layer 16.

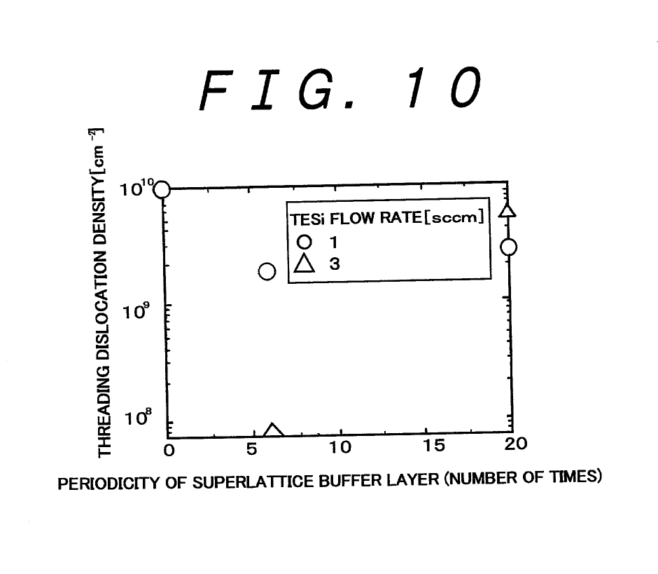

Moreover, as appeared in the graph of FIG. 10 indicating a relationship between periodicity of a low dislocation buffer layer 16 and threading dislocation density in a low dislocation buffer layer 16, when a periodicity of the low dislocation buffer layer 16 exceeds a certain number of times (twenty times in FIG. 10), threading dislocation density increases on the contrary. This phenomenon is considered to be in such that when the number of periodicity of the low dislocation buffer layer 16 becomes too high, crystallizability comes to be poor, so that threading dislocation does not decrease.

Thus, when a periodicity of the low dislocation buffer layer 16 is properly selected, it becomes possible to decrease effectively threading dislocation density. For instance, when a high-concentration impurity-containing nitride semiconductor layer 16a is prepared from Al_{0.15}Ga_{0.75}N containing Si as an impurity, a periodicity of the low dislocation buffer layer 16 is within a range of from three to fifty periods, and most effectively within a range of from five to ten periods in the former range.

As mentioned hereinafter, a composition of a nitride semiconductor and a type of impurities are not specifically limited, but in this case, the number of periodicity of a low dislocation buffer layer 16 is preferably within a range of from three to fifty periods, and most effectively within a range of from five to ten periods in the former range.

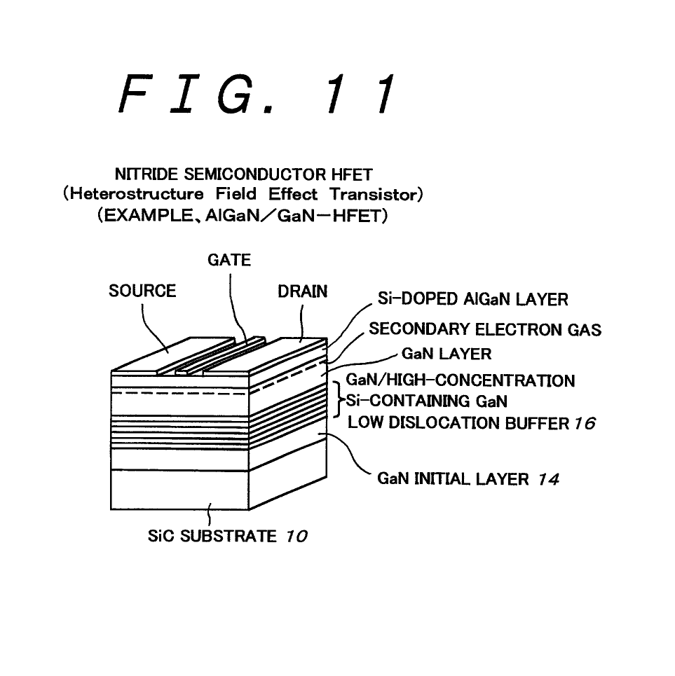

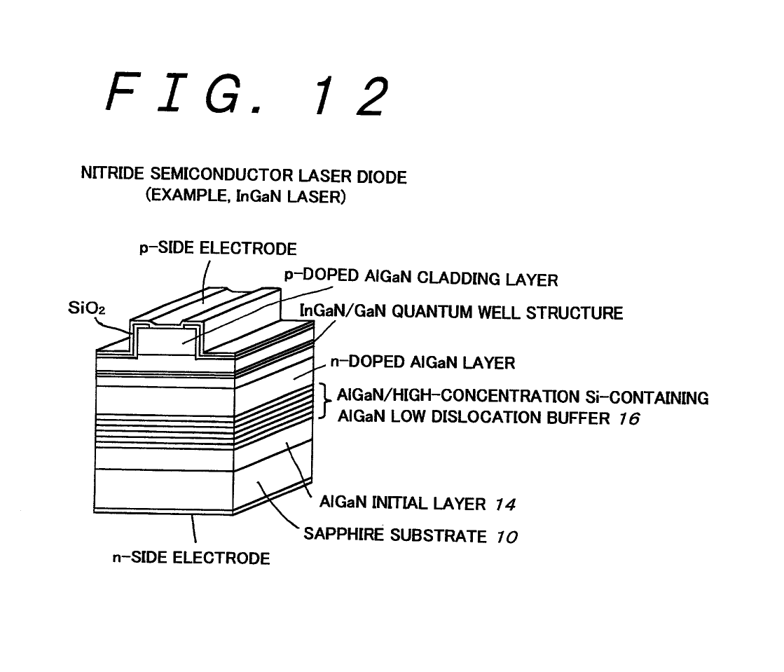

FIGS. 11 and 12 are perspective views each showing a structure of a device provided with a low dislocation buffer layer 16. Namely, FIG. 11 shows a nitride semiconductor HFET (Heterostructure Field Effect Transistor), and FIG. 12 is a nitride semiconductor laser diode.

In the nitride semiconductor HFET shown in FIG. 11, a GaN initial layer is formed as a second initial layer 14 on an SiC substrate as a substrate 10 (a first initial layer is omitted in this case).

On the GaN initial layer, a low dislocation buffer layer 16 (a high-concentration impurity-containing nitride semiconductor layer 16a is prepared from GaN containing Si as an impurity, while a non impurity-containing nitride semiconductor layer 16b is prepared from GaN) is formed.

Moreover, on the low dislocation buffer layer 16, a GaN layer as a nitride semiconductor that comes to be a device material for constituting a device structure, an Si-doped AlGaN layer is formed on the GaN layer, and the Si-doped AlGaN layer is provided with a source, a gate and a drain to fabricate a nitride semiconductor HFET.

Furthermore, in the nitride semiconductor laser diode shown in FIG. 12, an AlGaN initial layer is formed as a second initial layer 14 (a first initial layer is omitted in this case) on a sapphire substrate being a substrate 10 on the bottom of which has been provided with an n-side electrode.

On the AlGaN initial layer, a low dislocation buffer layer 16 (a high-concentration impurity-containing nitride semiconductor layer 16a is prepared from AlGaN containing Si as an impurity, while a non impurity-containing nitride semiconductor layer 16b is prepared from AlGaN) is formed.

Furthermore, on the low dislocation buffer layer 16, an n-doped AlGaN layer is formed as a nitride semiconductor that becomes a device material for constituting a device structure, an InGaN/GaN quantum well structure is defined on the n-doped AlGaN layer, a p-doped AlGaN cladding layer is formed on the InGaN/GaN quantum well structure, and a p-side electrode is formed on the p-doped AlGaN cladding layer through SiO₂.

As shown in the above-described FIGS. 11 and 12, a film formation of a nitride semiconductor that becomes a device material for constituting a device structure is made on the low dislocation buffer layer 16, whereby a variety of light-emitting devices, light-receiving devices, and electron devices can be prepared.

As mentioned above, the low dislocation buffer layer 16 can be prepared by an exactly in-situ simple process.

On the other hand, a conventional low dislocation technique of buffer layer has required complicated processes of several stages, besides, it is required to strictly control growth conditions for making vertical/horizontal enhanced growth.

According to the present invention, however, a low dislocation buffer layer 16 can be prepared by a simple process of only incorporating an impurity, and no strict control for growth conditions is required. Besides, it is possible to reduce a threading dislocation density up to around three-orders thereof as compared with that of a conventional buffer layer, so that the threading dislocation density can be reduced up to an order of 10⁷ cm⁻².

Furthermore, since the low dislocation buffer 16 can be prepared by a very simple process, the process of the present invention can be applied instantaneously to a production line of nitride semiconductor. Accordingly, it can be intended to achieve highly efficient light-emitting efficiency in light-emitting devices, to decrease dark current in light-receiving devices, and to decrease leak current in junction transistors and field effect transistors without requiring to change components employed at present.

Moreover, since it becomes possible to prepare a low dislocation buffer in which AlGaN having a high ratio of Al in the composition, it is also possible to realize ultraviolet light-receiving devices and light-emitting devices in 250 nm to 350 nm wavelength bands, or high-frequency and high pressure-proof junction transistors and field effect transistors in which wide band gap AlGaN is used.

For making the surface of a conventional buffer flat, formation of a thick film of about 3 μm to 10 μm is required, whereby there has been a problem of generating cracks. In this respect, however, a low dislocation buffer layer 16 of the present invention is excellent in its surface flatness, so that it is possible to reduce threading dislocations by means of a thin film having a total film thickness of a sub-micron. In other words, it is possible to realize a low density of threading dislocation by means of a thin film having a film thickness wherein no crack is produced in accordance with the low dislocation buffer layer 16 of the present invention.

In the prior art, materials for buffer are limited to GaN, AlGaN having a certain specified composition, or the like, because of requiring strict control for growth conditions. According to a low dislocation buffer layer 16 of the present invention, however, it is possible to prepare the low dislocation buffer layer 16 by using all the compositions of (Ga, Al, In)N as mentioned hereunder.

In a low dislocation buffer layer 16, when a type or a concentration of impurities is selected, it is possible to achieve low dislocation under wide growth conditions, so that there is flexibility in conditions for formation.

Reduction of threading dislocations can be observed in even the case where an impurity is incorporated uniformly into a nitride semiconductor without preparing a low dislocation buffer layer 16 from a superlattice structure of a high-concentration impurity-containing nitride semiconductor layer 16a and a non impurity-containing nitride semiconductor layer 16b. However, when a concentration of impurity is increased, cracks appear in a formed nitride semiconductor due to lattice strain. Hence, incorporation of impurity is not permitted only up to its doping level, so that effect in reduction of threading dislocations is small.

However, when a low dislocation buffer layer 16 is prepared from a supperlattice structure of a high-concentration impurity-containing nitride semiconductor layer 16a and a non impurity-containing nitride semiconductor layer 16b, it becomes possible to introduce an impurity of a high concentration exceeding its doping level. As a result, a film involving no crack can be prepared even in the case where an impurity having a high concentration wherein around several percents of a high-concentration impurity-containing nitride semiconductor exist, whereby it becomes possible to achieve effective reduction of threading dislocations of around three-orders lower than that of the prior art.

It is to be noted that the above-described embodiment may be modified as explained in the following paragraphs (1) through (12).

(1) Although MOCVD has been utilized for a process for producing a thin film such as a low dislocation buffer layer 16 in the above-described embodiment, the invention is not limited thereto as a matter of course, and various thin film producing techniques other than MOCVD such as MBE (Molecular Beam Epitaxy), CBE (Chemical Beam Epitaxy), HVPE (Halide Vapor Phase Epitaxy), GSMBE (Gas-source Molecular Beam Epitaxy), MOMBE (Metalorganic MBE), LPE (Liquid Phase Epitaxy), CVD (Chemical Vapor Deposition), sputtering, and vacuum evaporation method may be applied.

(2) While AlGaN having a composition ratio of Al_{0.15}Ga_{0.75}N has been used for a high-concentration impurity-containing nitride semiconductor and a non impurity-containing nitride semiconductor constituting a low dislocation buffer layer 16 in the above-described embodiment, the composition ratio is not limited to Al_{0.15}Ga_{0.75}N as a matter of course, and further a composition ratio of the high-concentration impurity-containing nitride semiconductor may differ from that of the non impurity-containing nitride semiconductor.

(3) Although AlGaN has been employed for a high-concentration impurity-containing nitride semiconductor and a non impurity-containing nitride semiconductor constituting a low dislocation buffer layer 16 in the above-described embodiment, the composition is not limited to the AlGaN as a matter of course, and, for example, all the incorporated compositions of (Ga, Al, In) N may be used, besides a composition of the high-concentration impurity-containing nitride semiconductor may differ from that of the non impurity-containing nitride semiconductor.

(4) In the above-described embodiment, Si (silicon) has been used as an impurity contained in a high-concentration impurity-containing nitride semiconductor constituting a low dislocation buffer layer 16, but the impurity is not limited to Si as a matter of course, and for instance, C (carbon), Mg (magnesium), or O (oxygen) may also be used.

(5) In the above-described embodiment, a film of a low dislocation buffer layer 16 having a superlattice structure composed of a high-concentration impurity-containing nitride semiconductor and a non impurity-containing nitride semiconductor has been formed at 1100° C., but the temperature is not limited thereto, and it may be properly selected within a range of, for example, from 600° C. to 1300° C. in response to each composition of the high-concentration impurity-containing nitride semiconductor and the non impurity-containing nitride semiconductor constituting the low dislocation buffer layer 16.

(6) Although silicon carbide (SiC), and more specifically 6H-SiC (0001) has been used as a substrate for forming a low dislocation buffer layer 16 having a superlattice structure composed of a high-concentration impurity-containing nitride semiconductor and a non impurity-containing nitride semiconductor in the above-described embodiment, the substrate is not limited thereto as a matter of course, and a substrate made of, for example, sapphire (Al_{2O}₃), silicon (Si), and gallium arsenide (GaAs) may also be used.

(7) While a film thickness of a high-concentration impurity-containing nitride semiconductor constituting a low dislocation buffer layer 16, that is, a thickness of a high-concentration impurity-containing nitride semiconductor layer 16a has been 20 nm in the above-described embodiment, the thickness is not limited thereto as a matter of course, and such a thickness may be properly controlled within a range of, for example, 1 nm to 100 nm.

(8) In the above-described embodiment, a film thickness of a non impurity-containing nitride semiconductor constituting a low dislocation buffer layer 16, that is, a thickness of the non impurity-containing nitride semiconductor layer 16b has been 80 nm, but the thickness is not limited thereto as a matter of course, and such a thickness may be properly controlled within a range of, for example, 5 nm to 500 nm.

(9) In the above-described embodiment, a repeated periodicity in case of laminating a pair of a certain high-concentration impurity-containing nitride semiconductor layer 16a and the following high-concentration impurity-containing nitride semiconductor layer 16a with a non impurity-containing nitride semiconductor layer 16b (or a distance defined between the pair of a certain high-concentration impurity-containing nitride semiconductor layer 16a and the following high-concentration impurity-containing nitride semiconductor layer 16a with the non impurity-containing nitride semiconductor layer 16b) has been 100 nm, but the distance (periodicity) is not limited to 100 nm as a matter of course, and it may be properly controlled within a range of, for example, 5 nm to 500 nm.

(10) While a layer thickness of a low dislocation buffer layer 16 has been 600 nm in the above-described embodiment, the layer thickness is not limited to 600 nm, and it may be properly controlled within a range of, for example, 0.3 μm to 5 μm.

(11) Although an AlN thin film has been formed between a 6H-SiC (0001) substrate and a low dislocation buffer layer 16 as a first initial layer 12, and further AlGaN has been formed as a second initial layer 14 in the above-described embodiment, the invention is not limited thereto as a matter of course, and for instance, either of the first initial layer 12 and the second initial layer 14 may only be formed, or the both of them may not be formed.

(12) The above-described embodiment may be properly combined with modified examples described in the above paragraphs (1) through (11), respectively.

Since the present invention has been constituted as described above, a buffer of a low dislocation density can be formed as a buffer layer to be formed between a substrate made of variety of materials and an epitaxial semiconductor layer in case of forming the epitaxial semiconductor layer of a thin or thick film of a nitride semiconductor such as GaN as a device material for constituting a predetermined device structure on the substrate, and further, in this case, no complicated process is required, and in addition, a thick film is not required for making a surface of the film flat. Accordingly, the present invention exhibits an excellent advantage to provide a low dislocation buffer that can be formed by a simple process for a short period of time, and there is no fear of producing cracks, and a process for the production thereof as well as a device provided with such low dislocation buffer.

It will be appreciated by those of ordinary skill in the art that the present invention can be embodied in other specific forms without departing from the spirit or essential characteristics thereof.

The presently disclosed embodiments are therefore considered in all respects to be illustrative and not restrictive. The scope of the invention is indicated by the appended claims rather than the foregoing description, and all changes that come within the meaning and range of equivalents thereof are intended to be embraced therein.

The entire disclosure of Japanese Patent Application No. 2000-368566 filed on Dec. 4, 2000 including specification, claims, drawing and summary are incorporated herein by reference in its entirety.

What is claimed is:

1. A low dislocation buffer formed between a substrate and a nitride semiconductor as a device material to be formed for constituting a device structure on said substrate, comprising:
a first layer made of a nitride semiconductor containing an impurity at a concentration exceeding its doping level being laminated a predetermined number of times alternately with a second layer made of a nitride semiconductor containing no impurity on the substrate to form a superlattice structure.

2. A low dislocation buffer as claimed in claim 1 wherein:
a concentration of an impurity contained in a nitride semiconductor for forming said first layer is from 10¹⁸ cm⁻³ to 10%.

3. A low dislocation buffer as claimed in any one of claims 1 and 2 wherein:
said impurity is Si (silicon), C (carbon), Mg (magnesium), or O (oxygen).

4. A low dislocation buffer as claimed in any one of claims 1 and 2 wherein:
a nitride semiconductor for forming said first layer or said second layer is a three-five nitride semiconductor.

5. A low dislocation buffer as claimed in claim 3 wherein:
a nitride semiconductor for forming said first layer or said second layer is a three-five nitride semiconductor.

6. A low dislocation buffer as claimed in any one of claims 1 and 2 wherein:
said substrate is made from Si (silicon), SiC (silicon carbide), Al₂O₃ (sapphire), or GaAs (gallium arsenide).

7. A low dislocation buffer as claimed in claim 3 wherein:
said substrate is made from Si (silicon), SiC (silicon carbide), Al₂O₃ (sapphire), or GaAs (gallium arsenide).

8. A low dislocation buffer as claimed in claim 4 wherein:
said substrate is made from Si (silicon), SiC (silicon carbide), Al₂O₃ (sapphire), or GaAs (gallium arsenide).

9. A low dislocation buffer as claimed in claim 5 wherein:
said substrate is made from Si (silicon), SiC (silicon carbide), Al₂O₃ (sapphire), or GaAs (gallium arsenide).

10. A process for the production of a low dislocation buffer formed between a substrate and a nitride semiconductor as a device material to be formed for constituting a device structure on said substrate, comprising:
a first step for forming either of a first layer made of a nitride semiconductor containing an impurity at a concentration exceeding a doping level or a second layer made of a nitride semiconductor containing no impurity;
a second step for forming either layer of said first layer and said second layer, which has not yet been formed by said first step on the layer, which has been formed by said first step; and
said first step and said second step being alternately repeated a predetermined number of times to laminate said first layer alternately with said second layer on the substrate at the predetermined number of times to form a superlattice structure.

11. A process for the production of a low dislocation buffer as claimed in claim 10 wherein:
a concentration of an impurity contained in a nitride semiconductor for forming said first layer is substantially 1% or more.

12. A process for the production of a low dislocation buffer as claimed in any one of claims 10 and 11 wherein:
said impurity is Si (silicon), C (carbon), Mg (magnesium), or O (oxygen).

13. A process for the production of a low dislocation buffer as claimed in any one of claims 10 and 11 wherein:
a nitride semiconductor for forming said first layer or said second layer is a three-five nitride semiconductor.

14. A process for the production of a low dislocation buffer as claimed in claim 12 wherein:
a nitride semiconductor for forming said first layer or said second layer is a three-five nitride semiconductor.

15. A process for the production of a low dislocation buffer as claimed in any one of claims 10 and 11 wherein:
said substrate is made from Si (silicon), SiC (silicon carbide), Al₂O₃ (sapphire), or GaAs (gallium arsenide).

16. A process for the production of a low dislocation buffer as claimed in claim 12 wherein:
said substrate is made from Si (silicon), SiC (silicon carbide), Al₂O₃ (sapphire), or GaAs (gallium arsenide).

17. A process for the production of a low dislocation buffer as claimed in claim 13 wherein:
said substrate is made from Si (silicon), SiC (silicon carbide), Al₂O₃ (sapphire), or GaAs (gallium arsenide).

18. A process for the production of a low dislocation buffer as claimed in claim 14 wherein:
said substrate is made from Si (silicon), SiC (silicon carbide), Al₂O₃ (sapphire), or GaAs (gallium arsenide).

19. A device provided with a low dislocation buffer, comprising:
said low dislocation buffer being prepared by forming a predetermined device structure on the low dislocation buffer as claimed in any one of claims 1 and 2 with the use of a nitride semiconductor as a device material.

20. A device provided with a low dislocation buffer, comprising:
said low dislocation buffer being prepared by forming a predetermined device structure on the low dislocation buffer as claimed in claim 3 with the use of a nitride semiconductor as a device material.

21. A device provided with a low dislocation buffer, comprising:
said low dislocation buffer being prepared by forming a predetermined device structure on the low dislocation buffer as claimed in claim 4 with the use of a nitride semiconductor as a device material.

22. A device provided with a low dislocation buffer, comprising:
said low dislocation buffer being prepared by forming a predetermined device structure on the low dislocation buffer as claimed in claim 5 with the use of a nitride semiconductor as a device material.

23. A device provided with a low dislocation buffer as claimed in claim 19 wherein:
a nitride semiconductor that comes to be a device material for constituting said device structure is a three-five nitride semiconductor.

24. A device provided with a low dislocation buffer as claimed in claim 20 wherein:
a nitride semiconductor that comes to be a device material for constituting said device structure is a three-five nitride semiconductor.

25. A device provided with a low dislocation buffer as claimed in claim 21 wherein:
a nitride semiconductor that comes to be a device material for constituting said device structure is a three-five nitride semiconductor.

26. A device provided with a low dislocation buffer as claimed in claim 22 wherein:
a nitride semiconductor that comes to be a device material for constituting said device structure is a three-five nitride semiconductor.
